(19) United States
(12) Patent Application Publication
(10) Pub. No.: US 2024/0404911 A1
(43) Pub. Date: Dec. 5, 2024

(54) SEMICONDUCTOR PACKAGE WITH IMPROVED HEAT DISSIPATION

(71) Applicant: JCET STATS ChipPAC Korea Limited, Incheon (KR)

(72) Inventors: SeungHyun LEE, Incheon (KR); HeeSoo LEE, Incheon (KR); YongMoo SHIN, Incheon (KR)

(21) Appl. No.: 18/670,747

(22) Filed: May 22, 2024

(30) Foreign Application Priority Data
May 29, 2023 (CN) 202310617908.6

(51) Int. Cl. H01L 23/367; H01L 23/00; H01L 25/065

(52) U.S. Cl. CPC H01L 23/3672; H01L 24/32; H01L 24/83; H01L 25/0657; H01L 2224/32245; H01L 2224/83; H01L 2225/06589

(57) ABSTRACT

A semiconductor package is provided. The semiconductor package includes a primary semiconductor die with a top surface, wherein the top surface comprising a first region and a second region besides the first region; an auxiliary semiconductor die attached on the first region of the top surface of the primary semiconductor die; a primary heat spreader assembly attached on the second region of the top surface of the primary semiconductor die; and an auxiliary heat spreader assembly attached on a top surface of the auxiliary semiconductor die, wherein the primary heat spreader assembly is thermally isolated from the auxiliary heat spreader assembly.

### TECHNICAL FIELD

The present application generally relates to semiconductor technology, and more particularly, to a semiconductor package with improved heat dissipation and a method for making a semiconductor package.

### BACKGROUND OF THE INVENTION

The semiconductor industry is constantly faced with complex integration challenges as consumers want their electronics to be smaller, faster and higher performance with more and more functionalities packed into a single device. In order to meet the needs of the consumers, more and more electronic components are tightly integrated. Yet, in conventional design, a common heat spreader may be provided for the overall heat dissipation, therefore, heat generated from an electronic component may be partially transferred to other electronic components undesirably through the common heat spreader. Thus, heat dissipation for the package may not be ideal. Therefore, the performance of the semiconductor package may be harmed.

Therefore, a need exists for a semiconductor package with improved heat dissipation.

### SUMMARY OF THE INVENTION

An objective of the present application is to provide a semiconductor package with improved heat dissipation.

According to an aspect of embodiments of the present application, a semiconductor package is provided. The semiconductor package comprises: a primary semiconductor die with a top surface, wherein the top surface comprising a first region and a second region besides the first region; an auxiliary semiconductor die attached on the first region of the top surface of the primary semiconductor die; a primary heat spreader assembly attached on the second region of the top surface of the primary semiconductor die; and an auxiliary heat spreader assembly attached on a top surface of the auxiliary semiconductor die, wherein the primary heat spreader assembly is thermally isolated from the auxiliary heat spreader assembly.

According to another aspect of embodiments of the present application. a method for making a semiconductor package is provided. The method comprises: providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die; attaching a primary heat spreader assembly on the second region of the top surface of the primary semiconductor die; and attaching an auxiliary heat spreader assembly on a top surface of the auxiliary semiconductor die, wherein the primary heat spreader assembly is thermally isolated from the auxiliary heat spreader assembly.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1A shows a cross-sectional view illustrating a semiconductor package according to an embodiment of the present application.

FIG. 1B shows a top view of the semiconductor package of FIG. 1A according to an embodiment of the present application.

FIGS. 2 and 3 show cross-sectional views of two semiconductor packages according to two embodiments of the present application, respectively.

FIGS. 4A to 4F show cross-sectional views illustrating a method for forming a semiconductor package according to an embodiment of the present application.

FIGS. 5A and 5B show cross-sectional views illustrating a method for forming a semiconductor package according to another embodiment of the present application.

FIGS. 6 and 7 show cross-sectional views of two semiconductor packages according to two embodiments of the present application, respectively.

The same reference numbers will be used throughout the drawings to refer to the same or like parts.

### DETAILED DESCRIPTION OF THE INVENTION

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

A semiconductor package may include at least one heat generating electronic component, and heat generated by these electronic components may not be ideally dissipated. For example, due to the compact structure, heat generated by one electronic component may be undesirably transferred to other electronic components. In view of this, the present application proposes a semiconductor package with improved heat dissipation, especially in a tight layout.

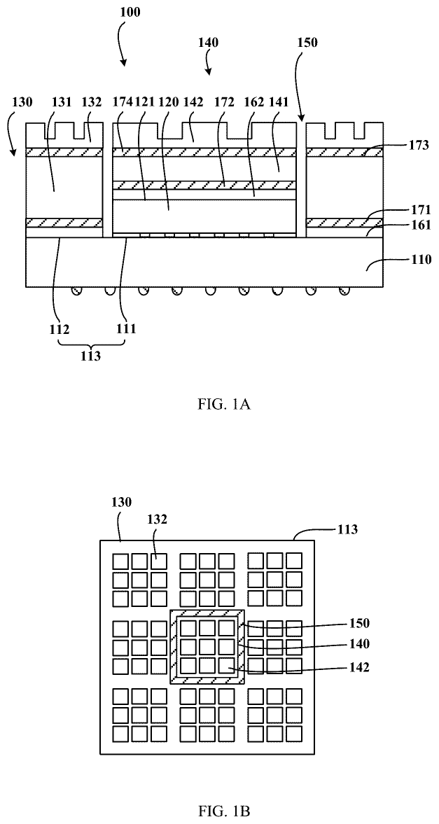

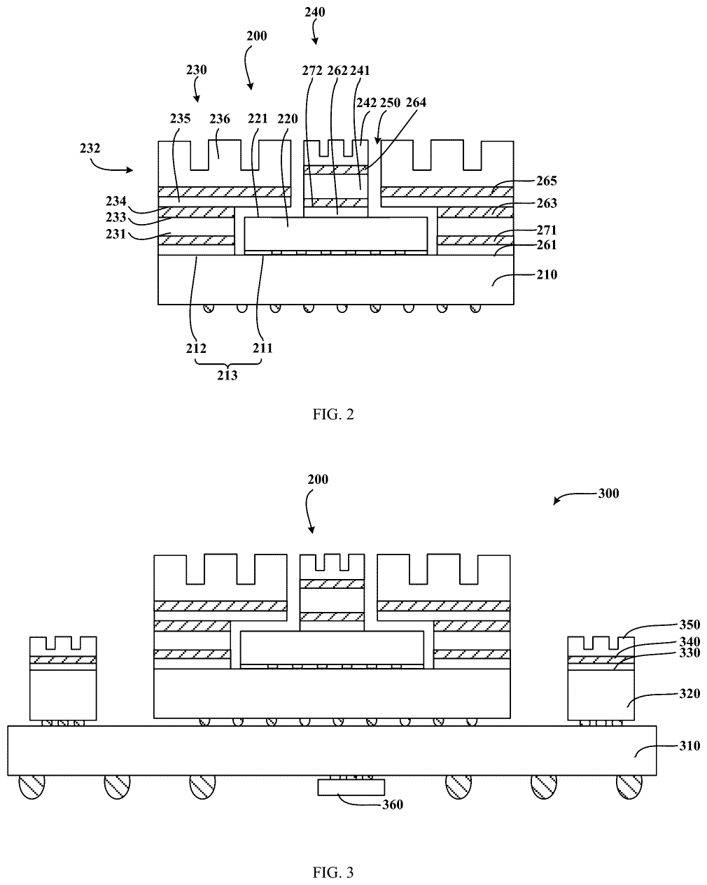

Referring to FIG. 1A, a cross-sectional view of a semiconductor package 100 according to an embodiment of the present application is shown. The semiconductor package 100 includes a primary semiconductor die 110 and an auxiliary semiconductor die 120. Specifically, the primary semiconductor die 110 has a top surface 113, wherein the top surface 113 includes a first region 111 and a second region 112 besides the first region 111. The auxiliary semiconductor die 120 is attached on the first region 111 of the primary semiconductor die 110. In some embodiments, the primary semiconductor die 110 may include a central processing unit (CPU) and the auxiliary semiconductor die 120 may include a memory chip. In some embodiments, the primary semiconductor die 110 and the auxiliary semiconductor die 120 are bonded together by hybrid bonding. In some embodiments, the hybrid bonding of the primary semiconductor die 110 and the auxiliary semiconductor die 120 can include a bonding surface (not shown) with a dielectric material and conductive interconnect structures that extend through the dielectric material. Preferably, the conductive interconnect structures may include copper posts. In some embodiments, the primary semiconductor die 110 may include through silicon vias (TSVs) (not shown) for desired vertical electrical connection.

Still referring to FIG. 1A, a primary heat spreader assembly 130 is attached on the second region 112 of the primary semiconductor die 110. Also, an auxiliary heat spreader assembly 140 is attached on a top surface 121 of the auxiliary semiconductor die 120. The primary heat spreader assembly 130 is thermally isolated from the auxiliary heat spreader assembly 140. Therefore, heat generated by the primary semiconductor die 110 may be dissipated by the primary heat spreader assembly 130, and heat generated by the auxiliary semiconductor die 120 may be dissipated by the auxiliary heat spreader assembly 140, respectively, minimizing heat transfer between the primary semiconductor die 110 and the auxiliary semiconductor die 120. In some embodiments, the primary semiconductor die 110 may include a CPU or similar computation or processing modules that may produce more heat and thus have a higher temperature, e.g. around 90 degrees Celsius, during operation, while the auxiliary semiconductor die 120 may include a memory module or other similar modules that may not have a significant power consumption thus and have a lower temperature, e.g., 60 degrees Celsius, during operation. In a conventional design where a common heat spreader is configured for both the primary semiconductor die and auxiliary semiconductor die, heat may be undesirably transferred to the memory module with a lower temperature. It can be seen that the discrete heat spreader assemblies proposed by the present application may be advantageous, since all or at least a majority of the heat generated by the primary semiconductor dice 110 with a higher temperature may be dissipated via the corresponding primary heat spreader assembly 130.

Still referring to FIG. 1A, in order to achieve thermal isolation between the primary heat spreader assembly 130 and the auxiliary heat spreader assembly 140, in some embodiments, a gap 150 is formed between the primary heat spreader assembly 130 and the auxiliary heat spreader assembly 140. In some embodiments, the gap 150 may be an air gap. In some other embodiments, the gap 150 can be filled with a thermal insulation material, such as epoxy, unsaturated polyesters, phenolics, adhesives, etc. Aspects of the present application are not limited thereto. Specifically, in order to form the gap 150, in some embodiments, as shown in FIG. 1A, the primary heat spreader assembly 130 covers an area smaller than that of the second region 112 of the primary semiconductor die 110, the auxiliary heat spreader assembly 140 may cover an area the same as that of the auxiliary semiconductor die 120. It can be understood that, in some embodiments, the auxiliary heat spreader assembly 140 may cover an area smaller than that of the auxiliary semiconductor die 120 to achieve a larger gap 150. It can also be understood that, in some embodiments, the primary heat spreader assembly 130 may cover an area the same as that of the second region 112 of the primary semiconductor die 110, while the auxiliary heat spreader assembly 140 may cover an area smaller than that of the auxiliary semiconductor die 120 to achieve the desired gap. It can be understood that, although the primary heat spreader assembly 130 and the auxiliary heat spreader assembly 140 are designed to be thermally isolated, they may be structurally connected, e.g., with thermally insulative material, such that they can be disposed on the semiconductor package 100 together in a single process. For example, the primary heat spreader assembly 130 and the auxiliary heat spreader assembly 140 may be structurally connected via thin connection rods. The thin connection rods may have a cross section area of 1%-10% of a corresponding cross section area of the semiconductor package 100. Therefore, the heat transfer via the thin connection rods between the primary heat spreader assembly 130 and the auxiliary heat spreader assembly 140 may be not substantial. In some other embodiments, the primary heat spreader assembly 130 and the auxiliary heat spreader assembly 140 may be together assembled to a mold including a thermal insulative material, such that they may be assembled beforehand to be further disposed on the semiconductor package 100 together while achieving thermal isolation with each other.

As shown in FIG. 1A, in some embodiments, the primary heat spreader assembly 130 is attached on the top surface 113 of the primary semiconductor die 110 via an adhesion layer 161 and a thermal interface material layer 171. Preferably, the adhesion layer 161 may include Ti, Ag, stainless steel. Preferably, the thermal interface material layer 171 may include a soldering type thermal interface material such as In, Ag, In—Ag or a combination thereof. Similarly, in some embodiments, the auxiliary heat spreader assembly 140 is attached on the top surface 121 of the auxiliary semiconductor die 120 via an adhesion layer 162 and a thermal interface material layer 172 thereon. Configuration of the adhesion layer 162 and the thermal interface material layer 172 may refer to the adhesion layer 161 and the thermal interface material layer 171, respectively.

Each of the primary heat spreader assembly 130 and the auxiliary heat spreader assembly 140 may be formed as one piece or may include multiple sub-components. It can also be understood that, every sub-component of each of the primary heat spreader assembly 130 and the auxiliary heat spreader assembly 140 may include multiple subsets with similar structures formed separately or integrally.

Referring to FIG. 1A, in some embodiments, the primary heat spreader assembly 130 includes a primary intermediate block 131 attached on the second region 112 of the primary semiconductor die 110, and a primary heat sink 132 attached on a top surface of the primary intermediate block 131 such as via a thermally conductive layer 173. Preferably, the primary heat sink 132 includes a set of primary heat sink fins. In some embodiments, the primary intermediate block 131 and/or the primary heat sink 132 may include aluminum or copper. It can be understood that, the primary intermediate block 131 and the primary heat sink 132 may include same or different materials. Configuration of the thermal interface material layer 173 may refer to the illustration of the thermal interface material layer 171.

Still referring to FIG. 1A, in some embodiments, the auxiliary heat spreader 140 includes an auxiliary intermediate block 141 attached on the top surface 121 of the auxiliary semiconductor die 120, and an auxiliary heat sink 142 attached on a top surface of the auxiliary intermediate block 141 such as via a thermally conductive layer 174. The auxiliary heat sink 142 may include a set of auxiliary heat sink fins. The configuration of the components may refer to the previous embodiments and will not be repeated herein.

FIG. 1B shows a top view of the semiconductor package of FIG. 1A according to an embodiment of the present application. In some embodiments, the auxiliary semiconductor die 120 shown in FIG. 1A is at an center of the top surface 113 of the primary semiconductor die 110. In a top view of such embodiment, as shown in FIG. 1B, the auxiliary heat spreader assembly 140 occupies a center of the top surface 113 of the primary semiconductor die, while the primary heat spreader assembly 130 occupies a peripheral area around the center area. Specifically, the auxiliary heat spreader assembly 140 includes the auxiliary heat sink 142 that may take the form of a set of auxiliary heat sink fins. Similarly, the primary heat spreader assembly 130 includes the auxiliary heat sink 132 that may take the form of a set of primary heat sink fins. The gap 150 thermally isolates the auxiliary heat spreader assembly 140 from the primary heat spreader assembly 130. The gap 150 may be an air gap exposing the top surface 113 of the primary semiconductor die. In some embodiments, the gap 150 may be formed with a thermal insulative material.

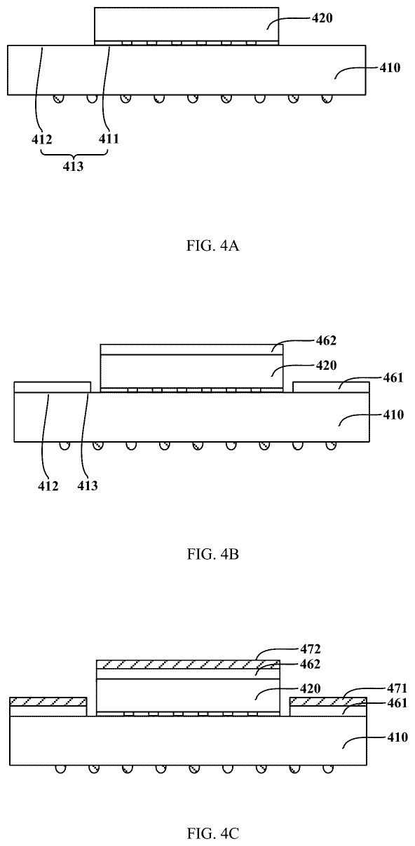

FIGS. 2 and 3 show cross-sectional views of two semiconductor packages according to two embodiments of the present application, respectively. In some embodiments, the primary semiconductor die generates more heat than the auxiliary semiconductor die, and the primary semiconductor die may require more heat dissipation than the auxiliary semiconductor die. In order to maintain space-efficiency while achieving ideal dissipation with different dissipation needs for the primary semiconductor die and auxiliary semiconductor die, a different heat configuration is proposed for the semiconductor package as shown in FIG. 2.

Referring to FIG. 2, similar to the semiconductor package 100 shown in FIG. 1A, the semiconductor package 200 includes a primary semiconductor die 210 having a top surface 213, which includes a first region 211 and a second region 212 besides the first region 211. An auxiliary semiconductor die 220 is attached on the first region 211 of the top surface 213 of the primary semiconductor die 210. A primary heat spreader assembly 230 is attached on the second region 212 of the primary semiconductor die 210 via such as an adhesion layer 261 and a thermal interface 271. An auxiliary heat spreader assembly 240 is attached on the auxiliary semiconductor die 220 via such as an adhesion layer 262 and a thermal interface material layer 272.

As shown in FIG. 2, in some embodiments, the primary heat spreader assembly 230 is configured such that it partially extends from the second region 212 of the top surface 213 of the primary semiconductor die 210 to a position above the top surface 221 of the auxiliary semiconductor die 220. Therefore, the primary heat spreader assembly 230 allows for a larger area for heat dissipation for the primary semiconductor die 210 attached thereunder, without changing an area of attachment between the primary heat spreader assembly 230 and the primary semiconductor die 210. Accordingly, the auxiliary heat spreader assembly 240 covers an area smaller than the top surface 221 of the auxiliary semiconductor die 220.

Each of the primary heat spreader assembly 230 and the auxiliary heat spreader assembly 240 may be formed as one piece or may include multiple sub-components. It can also be understood that, every sub-component of the primary heat spreader assembly 230 and the auxiliary heat spreader assembly 240 may include multiple subsets with similar structures formed separately or integrally.

Referring to FIG. 2, in some embodiments, the primary heat spreader assembly 230 includes a primary intermediate block 231 and a primary heat sink 232 attached thereon via such as a thermal interface material layer 263. Preferably, the top surface 233 of the primary intermediate block 231 levels with the top surface 221 of the auxiliary semiconductor die 220. In this way, a bottom surface 234 of the primary heat sink 232 may extend to a position above the top surface 221 of the auxiliary semiconductor die 220. A gap is formed between the primary heat spreader assembly 230, the auxiliary heat spreader assembly 240 and the auxiliary semiconductor die 220, while the primary heat sink 232 of the primary heat spreader assembly 230 almost aligns with the top surface 221 of the auxiliary semiconductor die 220, without wasting the space between the primary heat spreader assembly 230, the auxiliary heat spreader assembly 240 and the auxiliary semiconductor die 220.

Still referring to FIG. 2, in some embodiments, the primary heat sink 232 may further include a primary heat sink base 235 and a set of primary heat sink fins 236 extending from the primary heat sink base 235. As mentioned above, the primary heat sink base 235, as a bottom portion of the primary heat sink 232, partially extends to a position above the top surface 221 of the auxiliary semiconductor die 220. In some embodiments, the set of primary heat sink fins 236 may be fully supported by the primary heat sink base 235 via such as a thermal interface material layer 265. The configuration of the components may refer to the previous embodiments and will not be repeated herein.

In some embodiments, the auxiliary heat spreader assembly 240 may also include multiple sub-components. As shown in FIG. 2, the auxiliary heat spreader assembly 240 may include an auxiliary intermediate block 241 and an auxiliary heat sink 242 attached thereon via such as a thermal interface material layer 264.

It can be understood that, the primary heat spreader assembly 230 may also laterally extend to an area larger than a top surface of the primary semiconductor die 210 as desired.

The semiconductor package 200 shown in FIG. 2 utilizes the space above the primary semiconductor die 210 and the auxiliary semiconductor die 220 efficiently. The semiconductor package 200 may enable efficient heat dissipation for the primary semiconductor die 210, especially for a tight layout.

FIG. 3 illustrates a semiconductor package 300 with the semiconductor package 200 shown in FIG. 2 formed therein. In some embodiments, the semiconductor package 300 may include a substrate 310, the semiconductor package 200 formed on a top surface of the substrate 310, and another electronic component 320 formed thereon. The another electronic component 320 may be formed with an adhesion layer 330, a thermal interface material layer 340, and a heat sink 350. In some embodiments, the another electronic component 320 includes a high bandwidth memory (HBM). In some embodiments, another semiconductor package 360 is attached to a bottom surface of the substrate 310.

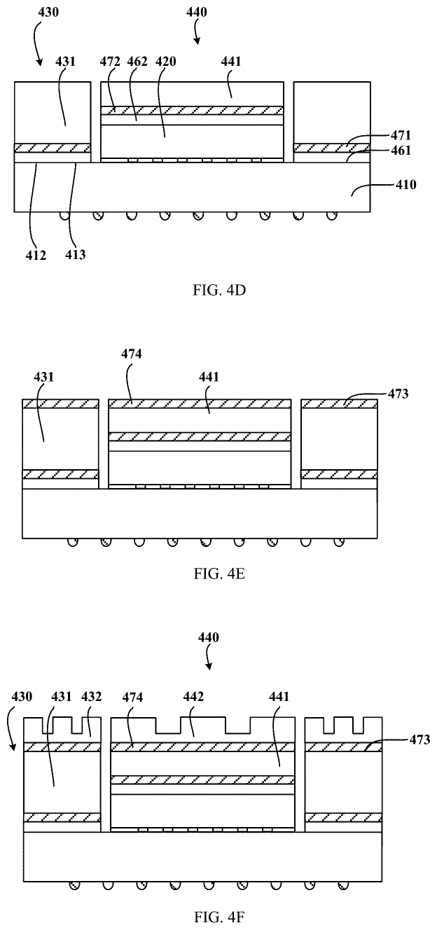

FIGS. 4A to 4F show cross-sectional views illustrating a method for forming a semiconductor package as shown in FIG. 1A.

Referring to FIG. 4A, a semiconductor die stack is provided. Specifically, the semiconductor stack includes a primary semiconductor die 410 and an auxiliary semiconductor die 420. The primary semiconductor die 410 includes a top surface 413 including a first region 411 and a second region 412 besides the first region 411. The auxiliary semiconductor die 420 is attached onto the first region 411.

Referring to FIG. 4B, in some embodiments, an adhesion layer 461 is formed on the second region 412 of the primary semiconductor die 410. An adhesion layer 462 is also formed on a top surface of the auxiliary semiconductor die 420. The adhesion layer 461 and 462 may be formed at the same time or at different times with the same material or different materials. In some embodiments, the adhesion layer 461 may partially or fully cover the second region 412 of the primary semiconductor die 410. The adhesion layer 461 or 462 may facilitate a relatively complete and uniform adhesion of other components thereon. In some embodiments, the adhesion layer 461 or 462 may be formed by a metal deposition process such as sputtering, electrolytic plating, and electroless plating.

Referring to FIG. 4C, in some embodiments, a thermal interface material layer 471 is formed on the adhesion layer 461. Similarly, a thermal interface material layer 472 is formed on the adhesion layer 462. The thermal interface material layer 471 or 472 may be formed by applying thermal epoxy, thermal epoxy resin, thermal conductive paste, aluminum oxide, zinc oxide, boron nitride, pulverized silver, thermal grease or other similar materials onto a desired area for attachment. Preferably, the thermal interface material layer 471 or 472 is formed by dispensing a soldering type thermal interface material, such as liquid metal and solder paste.

Referring to FIG. 4D, in some embodiments, a primary intermediate block 431 of the primary heat spreader assembly 430 is attached on the second region 412 of the primary semiconductor die 410, such as over the adhesion layer 461 and the thermal interface material layer 471. Similarly, an auxiliary intermediate block 441 of an auxiliary heat spreader 440 is attached on a top surface of the auxiliary semiconductor die 420, such as over the adhesion layer 462 and the thermal interface material layer 472. It can be understood that, the primary intermediate block 431 and the auxiliary intermediate block 441 may be attached at the same time or at different times.

Referring to FIG. 4E, in some embodiments, a thermal interface material layer 473 is formed on the primary intermediate block 431, and a thermal interface material layer 474 is formed on the auxiliary intermediate block 441. The thermal interface material layers 473 and 474 may be formed at the same time or at different times with the same material or different materials. The configuration of the components may refer to the previous embodiments and will not be repeated herein.

Referring to FIG. 4F, in some embodiments, a primary heat sink 432 of the primary heat spreader assembly 430 is attached on a top surface of the primary intermediate block 431 such as over the thermal interface material layer 473. Also, an auxiliary heat sink 442 of the auxiliary heat spreader assembly 440 is attached on a top surface of the auxiliary intermediate block 441, such as over the thermal interface material layer 474. In some embodiments, the auxiliary heat sink 442 includes a set of auxiliary heat sink fins.

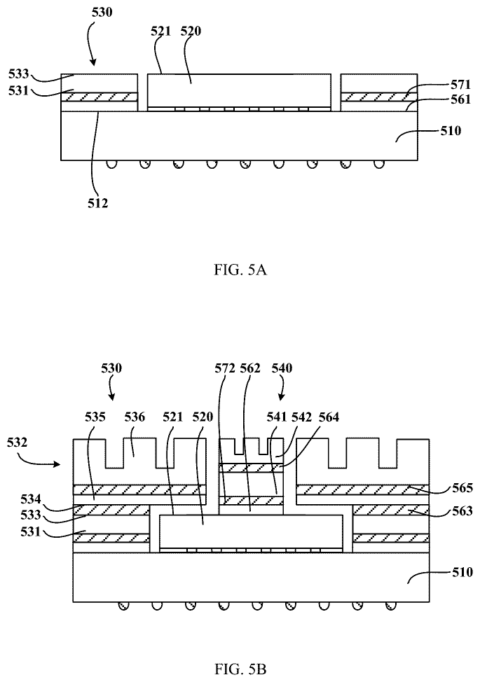

FIGS. 5A and 5B show cross-sectional views illustrating a method for forming a semiconductor package according to another embodiment of the present application. Herein, similar steps may refer to the previous embodiments and will not be repeated herein.

Referring to FIG. 5A, a primary semiconductor die 510 and an auxiliary semiconductor die 520 are provided. In some embodiments, an adhesion layer 561 and a thermal interface material layer 571 are formed on a second region 512 of the primary semiconductor die 510 for further attaching a primary heat spreader assembly 530 thereon. Preferably, a top surface 533 of the primary intermediate block 531 of the primary heat spreader assembly 530 levels with a top surface 521 of the auxiliary semiconductor die 520. Therefore, in further steps, a primary heat sink may be attached on the primary intermediate block 531 and extend to a position above the top surface 521 of the auxiliary semiconductor die 520. A bottom surface of the primary heat sink almost aligns with the top surface 521 of the auxiliary semiconductor die 520, without wasting space between the primary heat spreader assembly 530, an auxiliary heat spreader assembly attached on the auxiliary semiconductor die 520 (not shown), and the auxiliary semiconductor die 520.

Referring to FIG. 5B, a primary heat sink 532 including a primary heat sink base 535 and a set of primary heat sink fins 536 is attached on the primary intermediate block 531 via such as a thermal interface material layer 563. The set of primary heat sink fins 536 may be attached on the primary heat sink base 535 via such as a thermal interface material layer 565. Specifically, the primary heat sink base 535 partially extends to a position above the top surface 521 of the auxiliary semiconductor die 520. Thereby, in the case where the primary semiconductor die 510 desires more heat dissipation than the auxiliary semiconductor die 520, the primary semiconductor die 510 may have a relatively larger area for heat dissipation, and a limited space over the primary semiconductor die 510 and the auxiliary semiconductor die 520 may be utilized efficiently. In some embodiments, an auxiliary heat spreader assembly 540 is attached on the top surface 521 of the auxiliary semiconductor die 520 via such as an adhesion layer 562 and a thermal interface material layer 572. In some embodiments, the auxiliary heat spreader assembly 540 may include multiple sub-components such as an auxiliary intermediate block 541 and an auxiliary heat sink 542 attached thereon. The auxiliary intermediate block 541 and the auxiliary heat sink 542 may be attached via a thermal interface material layer 564. In some embodiments, the auxiliary heat sink 542 may include a set of auxiliary heat sink fins.

Therefore, as shown in FIG. 5B, in the semiconductor package, heat generated by the primary semiconductor die 510 and the auxiliary semiconductor die 520 may be dissipated by two discrete heat spreader assemblies, therefore, heat generated by the primary semiconductor die 510 may not be transferred undesirably via a common heat spreader to the auxiliary semiconductor die 520. Also, the space over the semiconductor dice 510 and 520 can be efficiently utilized to adapt that the primary semiconductor die requires more heat dissipation. In the present application, the gap between the semiconductor dice may be filled with a heat insulative material to further enhance heat isolation between the respective heat spreader assemblies.

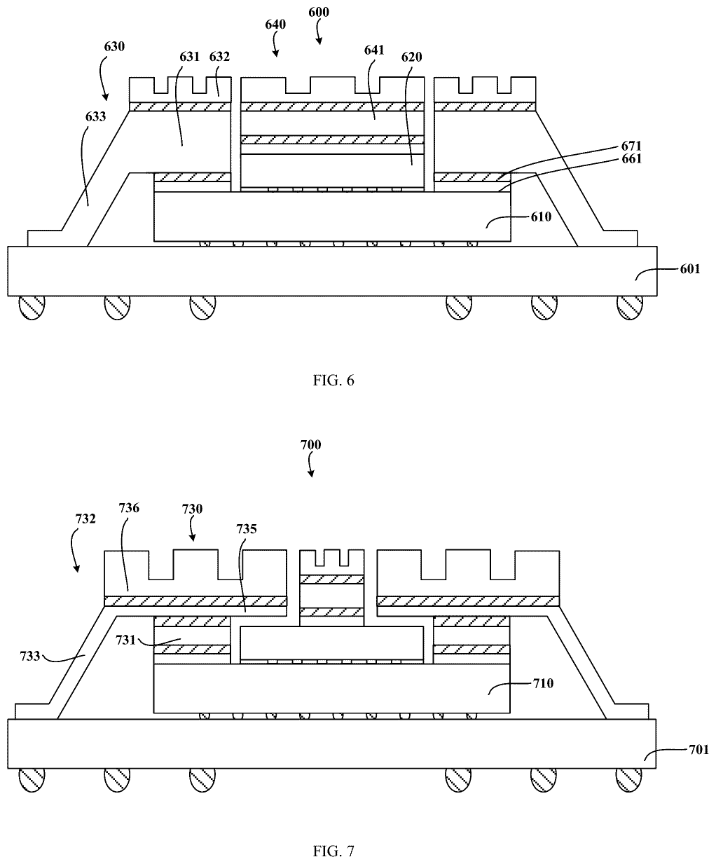

In the present invention, the primary heat spreader assembly and/or the auxiliary heat spreader assembly may include supportive structures as shown in FIGS. 6 and 7.

Referring to FIG. 6, the semiconductor package 600 is similar as the semiconductor package 100 shown in FIG. 1A. The primary semiconductor die 610 and the auxiliary semiconductor die 620 are stacked. Different from the semiconductor package 100, a primary heat spreader assembly 630 may include a supportive structure extending to a substrate 601. Specifically, a primary intermediate block 631 of the primary heat spreader assembly 630 may extend to attach to a top surface of the substrate 601 with a primary leg portion 633. The primary intermediate block 631 may physically and stably support structures thereon, e.g. the primary heat sink 632. In the case where the primary intermediate block 631 extends beyond the primary semiconductor die 610, the primary heat sink 632 thereon may accordingly occupy a relatively larger area and provide enhanced heat dissipation.

Still referring to FIG. 6, in some embodiments, the primary leg portion 633 may be formed at two sides or four sides above the primary semiconductor die 610. In some embodiments, similar as the supportive structure of the primary heat spreader assembly 630, the auxiliary heat spreader assembly 640 may also include supportive structure, for example, an auxiliary leg portion (not shown) extending to the substrate 601. The auxiliary leg portion of the auxiliary heat spreader assembly 640 and the primary leg portion 633 of the primary heat spreader assembly 630 may extend from different height and/or at different directions to efficiently use a limited space.

Still referring to FIG. 6, in some embodiments, the primary intermediate block 631 may be metal such as Cu for optimal heat dissipation. In some other embodiments, the primary intermediate block 631 may be Si. The primary intermediate block 631 may be structurally supportive and provides height for the primary heat sink 632 thereon. In some embodiments, the primary intermediate block 631 may be attached on a top surface of the primary semiconductor die 610 without the adhesion layer 661 or the thermal interface material layer 671.

Referring to FIG. 7, similar as shown in FIG. 6, the semiconductor package 700 may also include supportive structure. In some embodiments, the primary heat spreader assembly 730 may include a primary intermediate block 731 attached on the primary semiconductor die 710 and a primary heat sink 732 on the primary intermediate block 731. Specifically, the primary heat sink 732 may include primary heat sink base 735 and a set of primary heat sink fins 736. The primary heat sink base 735 may include a leg portion 733 extending to attach to the substrate 701. The leg portion 733 may support the set of primary heat sink fins 736 and provide a larger area for the set of primary heat sink fins 736. The configuration of the components may refer to the previous embodiments and will not be repeated herein.

The discussion herein included numerous illustrative figures that showed various portions of a semiconductor package and method for forming a semiconductor package. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

1. A semiconductor package, comprising:
a primary semiconductor die with a top surface, wherein the top surface comprises a first region and a second region besides the first region;
an auxiliary semiconductor die attached on the first region of the top surface of the primary semiconductor die;
a primary heat spreader assembly attached on the second region of the top surface of the primary semiconductor die; and
an auxiliary heat spreader assembly attached on a top surface of the auxiliary semiconductor die, wherein the primary heat spreader assembly is thermally isolated from the auxiliary heat spreader assembly.

2. The semiconductor package of claim 1, wherein the primary heat spreader assembly partially extends from the second region of the top surface of the primary semiconductor die to a position above the top surface of the auxiliary semiconductor die.

3. The semiconductor package of claim 1, wherein the primary heat spreader assembly comprises:
a primary intermediate block attached on the second region of the top surface of the primary semiconductor die; and
a primary heat sink attached on a top surface of the primary intermediate block.

4. The semiconductor package of claim 3, wherein
the top surface of the primary intermediate block levels with the top surface of the auxiliary semiconductor die; and
a bottom surface of the primary heat sink partially extends to a position above the top surface of the auxiliary semiconductor die.

5. The semiconductor package of claim 4, wherein the primary heat sink comprises:
a primary heat sink base, wherein the primary heat sink base partially extends to a position above the top surface of the auxiliary semiconductor die; and
a set of primary heat sink fins extending from the primary heat sink base.

6. The semiconductor package of claim 1, wherein the primary heat spreader assembly is attached on the top surface of the primary semiconductor die via an adhesion layer and a thermal interface material layer on the adhesion layer, and the auxiliary heat spreader assembly is attached to the auxiliary semiconductor die via an adhesion layer and a thermal interface material layer.

7. The semiconductor package of claim 1, wherein the auxiliary heat spreader assembly comprises:
an auxiliary intermediate block attached on the top surface of the auxiliary semiconductor die; and
an auxiliary heat sink attached on a top surface of the auxiliary intermediate block, comprising a set of auxiliary heat sink fins.

8. A method for forming a semiconductor package, comprising:
providing a semiconductor die stack with a primary semiconductor die and an auxiliary semiconductor die, wherein the primary semiconductor die comprises a top surface comprising a first region and a second region besides the first region, wherein the auxiliary semiconductor die is attached onto the first region of the top surface of the primary semiconductor die;
attaching a primary heat spreader assembly on the second region of the top surface of the primary semiconductor die; and
attaching an auxiliary heat spreader assembly on a top surface of the auxiliary semiconductor die, wherein the primary heat spreader assembly is thermally isolated from the auxiliary heat spreader assembly.

9. The method of claim 8, wherein upon attaching a primary heat spreader assembly, the primary heat spreader assembly partially extends from the second region of the top surface of the primary semiconductor die to a position above the top surface of the auxiliary semiconductor die.

10. The method of claim 8, wherein attaching a primary heat spreader assembly comprises:
attaching a primary intermediate block on the second region of the top surface of the primary semiconductor die; and
attaching a primary heat sink on a top surface of the primary intermediate block.

11. The method of claim 10, wherein
upon attaching a primary intermediate block, the top surface of the primary intermediate block levels with the top surface of the auxiliary semiconductor die; and
upon attaching a primary heat sink, a bottom surface of the primary heat sink partially extends to a position above the top surface of the auxiliary semiconductor die.

12. The method of claim 11, wherein attaching a primary heat sink comprises:
attaching a primary heat sink base, wherein the primary heat sink base partially extends to a position above the top surface of the auxiliary semiconductor die; and
attaching a set of primary heat sink fins extending from the primary heat sink base.

13. The method of claim 8, wherein attaching a primary heat spreader assembly comprises:
forming an adhesion layer and a thermal interface material layer; and
wherein attaching an auxiliary heat spreader assembly comprises:
forming an adhesion layer and a thermal interface material layer.

14. The method of claim 8, wherein attaching an auxiliary heat spreader assembly comprises:
attaching an auxiliary intermediate block on the top surface of the auxiliary semiconductor die; and
attaching an auxiliary heat sink on a top surface of the auxiliary intermediate block, wherein the auxiliary heat sink comprises a set of auxiliary heat sink fins.
